(19) United States
(12) Patent Application Publication
(10) Pub. No.: US 2005/0250343 A1
(43) Pub. Date: Nov. 10, 2005

(54) Method of manufacturing a semiconductor device

(76) Inventors: Kong-Soo Lee, Hwasung-si (KR); Sang-Jin Park, Sungnam-si (KR); Bong-Hyun Kim, Incheon-si (KR); Ki-Hyun Hwang, Sungnam-si (KR)

Correspondence Address: HARNESS, DICKEY & PIERCE, P.L.C., P.O. BOX 8910, RESTON, VA, 20195, US

(21) Appl. No.: 11/125,198

(22) Filed: May 10, 2005

(30) Foreign Application Priority Data
May 10, 2004 (KR) 2004-32585

(51) Int. Cl. H01B 7/29; H01L 21/469; H01L 21/31; H01B 11/06

(52) U.S. Cl. 438/765

(57) ABSTRACT

An insulation layer containing bonds of Si—N may be formed on a substrate. An electrode may be formed on the insulation layer. The substrate and the insulation layer exposed by the electrode may be treated with free radicals, which may improve the insulation capacity of the insulation layer and/or partially oxidize a surface of the substrate. The bonds of Si—N may be transformed into bonds of Si—O such that damage to the substrate and the insulation layer may be cured.

### CROSS REFERENCE TO RELATED APPLICATION

This application claims priority under 35 USC §119 to Korean Patent Application No. 2004-0032585 filed on May 10, 2004 in the Korean Intellectual Property Office (KIPO), the contents of which are incorporated herein by reference in their entirety.

### BACKGROUND OF THE INVENTION

1. Field of the Invention

Example embodiments of the present invention relate to methods for manufacturing semiconductor devices.

2. Description of the Conventional Art

Conventional semiconductor devices may include a CMOS (complementary metal-oxide-semiconductor) including a NMOS (negative-channel MOS) transistor and a PMOS (positive-channel MOS). The CMOS device may have, for example, a lower power consumption, improved response speed, improved noise margin, improved performance characteristic, etc.

Conventional DRAM (dynamic random access memory) devices may apply the CMOS device in a peripheral portion of the circuitry. In a conventional DRAM device, N+ polycrystalline silicon may be employed as a material for the gate electrode of both NMOS and PMOS transistors. This method may be referred to as a single gate technique.

In the single gate technique, the PMOS transistor, which may be a buried channel transistor, may exhibit a higher threshold voltage, as compared with the NMOS transistor, which may be a surface channel transistor.

The difference in the threshold voltages may not result in problems with the conventional DRAM devices, but may present a problem in a DRAM device with lower power consumption.

In a dual gate technique, N+ polycrystalline silicon and P+ polycrystalline silicon may be used as a gate electrode material of the NMOS transistor and the PMOS transistor, respectively. P+ polycrystalline silicon may be used as the gate electrode material of the PMOS transistor, and may serve as a surface channel transistor in both the NMOS and PMOS transistors such that the threshold voltage may be lowered.

If P+ polycrystalline silicon is applied to the PMOS transistor, boron implanted therein may have a higher diffusivity, and the boron may diffuse and penetrate the channel region in response to heat associated with subsequent processes. Thus, a mobility of carriers and the current driving capability of a device may be lowered.

In order to suppress the diffusive penetration of boron, an oxide/nitride layer or silicon nitride layer containing bonds of Si—N may be used as part of the gate insulation layer.

If a gate patterning process is used to form a gate electrode, a dry etching process may cause damage to the surface of the gate electrode, a gate insulation layer exposed by the gate electrode, and the semiconductor substrate. Thus, the quality of the gate insulation layer may be degraded and/or the refresh characteristic of a DRAM device may deteriorate.

An oxidation process for curing the damage may be carried out to repair the damage. The oxidation process may be referred to as a gate polysilicon re-oxidation process. The gate polysilicon re-oxidation process may be preformed by a dry oxidation process or a wet oxidation process.

In the gate electrode with a gate insulation layer containing bonds of Si—N, which may be used for suppressing the diffusive penetration of boron, the bonds of Si—N may impede the re-oxidation process. Prior to the re-oxidation process, the bonds of Si—N may be transformed into bonds of Si—O, respectively. A common dry or wet oxidation process may not be suitable for converting the bonds of Si—N into the bonds of Si—O.

### SUMMARY OF THE INVENTION

Example embodiments of the present invention relate a method of manufacturing a semiconductor device, in which an oxidation process may be carried out to cure damages, which may occur in, for example, an etching process for forming a gate electrode of the semiconductor device.

Example embodiments of the present invention provide methods of manufacturing semiconductor devices, in which the properties of a gate insulation layer containing bonds of Si—N may be improved.

In example embodiments of the present invention, as bonds of Si—N are transformed into bonds of Si—O, damage to a semiconductor substrate and an insulation layer may be cured such that an insulation structure of a higher quality may be obtained and/or refresh characteristics of a semiconductor device including the insulation structure may be enhanced.

An example embodiment of the present invention provides a method of manufacturing a semiconductor device, in which an insulation layer, which may contain bonds of Si—N, may be formed on a substrate. An electrode may be formed on the insulation layer, and a surface of the substrate and the insulation layer, exposed by the electrode, may be treated with oxygen radicals, which may improve the insulation capacity of the insulation layer and/or at least partially oxidize the surface of the substrate.

Another example embodiment of the present invention provides a method of manufacturing a semiconductor device in which an insulation layer may be formed on a substrate. An electrode may be formed on the insulation layer, and the substrate and the insulation layer, which may be exposed by the electrode, may be treated with free radicals, which may improve an insulation capacity of the insulation layer and/or at least partially oxidize a surface of the substrate.

In example embodiments of the present invention, a spacer may be formed on a sidewall of the electrode, and the spacer may be treated with oxygen radicals.

In example embodiments of the present invention, a spacer may be formed on a sidewall of the electrode, and may be treated with free radicals.

In example embodiments of the present invention, the oxygen radicals may be obtained using a gas mixture including at least one of H₂ and O₂.

In example embodiments of the present invention, the oxygen radicals may be formed at a temperature of above about 800° C. and/or under a pressure of below about 1 Torr.

In example embodiments of the present invention, the insulation layer may be formed by forming an oxide film on the semiconductor substrate, and by forming a nitride film on the oxide film. The oxide film may include silicon oxide, and the nitride film may include silicon nitride.

In example embodiments of the present invention, the insulation layer may be formed by forming an oxide film on the semiconductor substrate, and nitrifying an upper portion of the oxide film in a nitrogen atmosphere to form an oxynitride film. The oxide film may include silicon oxide, and the oxynitride film may include silicon oxynitride.

In example embodiments of the present invention, the electrode may be formed by forming a conductive layer on the insulation layer, forming a mask layer on the conductive layer, and forming a mask pattern and an electrode by patterning the mask layer and the conductive layer.

In example embodiments of the present invention, the electrode may be formed by forming a polysilicon film doped with impurities on the insulation layer, and forming a metal silicide film on the polysilicon film. The impurities may include at least one of boron and BF₂.

### BRIEF DESCRIPTION OF THE DRAWINGS

Example embodiments of the present invention will be apparent from the following discussion with reference to the accompanying drawings. The drawings are not necessarily to scale, emphasis instead being placed upon illustrating the principles of the invention. Like reference characters refer to like elements throughout the drawings.

FIGS. 1 to 5 are cross-sectional views illustrating a method of manufacturing a semiconductor device, according to an example embodiment of the present invention;

FIGS. 6 to 10 are cross-sectional views illustrating a method of manufacturing a semiconductor device, according to another example embodiment of the present invention; and

FIGS. 11 to 12 are cross-sectional views illustrating a method of manufacturing a semiconductor device, according to another example embodiment of the present invention.

### DETAILED DESCRIPTION OF EXAMPLE EMBODIMENTS OF THE PRESENT INVENTION

Example embodiments of the present invention will now be described more fully hereinafter with reference to the accompanying drawings. It will be understood that when an element such as a layer, region or substrate is referred to as being “on” or “onto” another element, it may be directly, or indirectly, on the other element or intervening elements may be present.

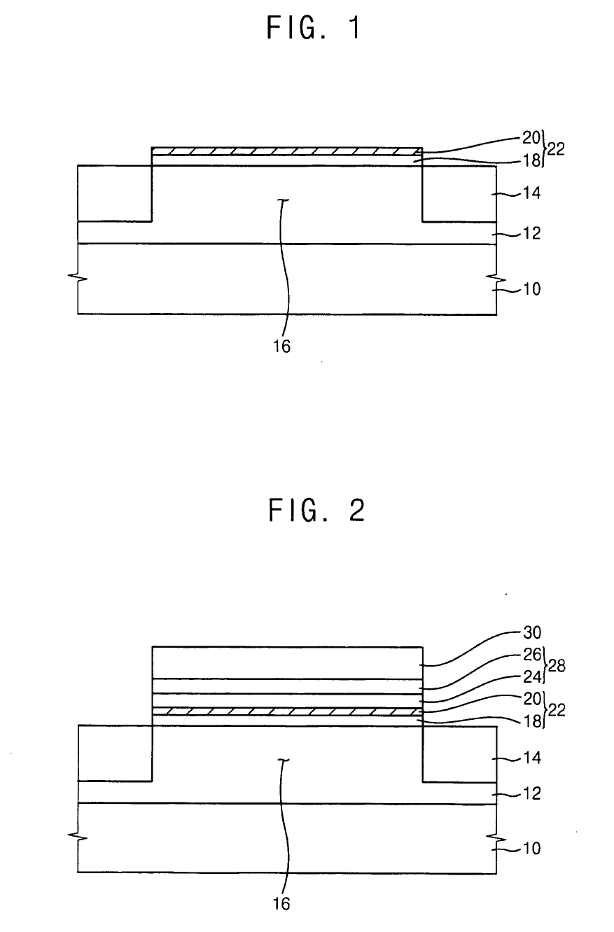

FIGS. 1 to 5 are cross-sectional views illustrating a method of manufacturing a PMOS transistor, according to an example embodiment of the present invention.

Referring to FIG. 1, an N-type well 12 doped with N-type impurities may be formed on a semiconductor substrate 10 doped with P-type impurities. The semiconductor substrate 10 may be, for example, a silicon wafer, or any other suitable substrate.

An isolation layer 14 may be formed on the N-type well 12. The isolation layer 14 may be formed on the N-type well 12 using, for example, a local oxidation of silicon (LOCOS) process, a shallow trench isolation (STI) process, or any other suitable oxidation and/or isolation process. When the isolation layer 14 is formed on the semiconductor substrate 10, an active region 16 may be defined on the semiconductor substrate 10.

A gate insulation layer 22, which may include bonds of Si—N, or any other suitable elements, may be formed on the active region 16 of the semiconductor substrate 10. The gate insulation layer 22 may include a first oxide film 18 and a nitride film 20, which may be formed (e.g., sequentially formed) on the active region 16. The first oxide film 18 may include, for example, silicon oxide (or any other suitable oxide material) and the nitride film 20 may include, for example, silicon nitride (or any other suitable nitride material). If the first oxide film 18 includes silicon oxide and the nitride film 20 includes silicon nitride the gate insulation layer 22 may include the bonds of Si—N therein.

The first oxide film 18 may be formed on the active region 16 by oxidizing a surface portion of the semiconductor substrate 10. The first oxide film 18 may be formed using, for example, a rapid thermal oxidation process, a furnace thermal oxidation process, a plasma oxidation process, or any other suitable oxidation process. When the first oxide film 18 is formed using, for example, the rapid thermal oxidation process, the surface portion of the semiconductor substrate 10 may be oxidized at a temperature of, for example, about 800° C. to about 950° C., and/or under a pressure of, for example, about several Torr for about 10 seconds to about 30 seconds, which may form the first oxide film 18 on the active region 16 of the semiconductor substrate 10. A tungsten halogen lamp, an arc lamp, or any other suitable heating device may be employed to heat the semiconductor substrate 10.

The nitride film 20 may be formed on the first oxide film 18 using, for example, an atomic layer deposition (ALD) process, a low pressure chemical vapor deposition (LPCVD) process, or any other suitable deposition process. In the ALD or LPCVD process for forming the nitride film 20, a silicon source containing, for example, SiH₄, SiCl₂H₂, SiCl₄, or any other suitable silicon source, may be used and a nitrogen source containing, for example, N₂, NH₃, N₂O, or any other suitable nitrogen source may be also employed.

Referring to FIG. 2, a gate conductive layer 28 may be formed on the gate insulation layer 22 including the bonds of Si—N. The gate conductive layer 28 may include, for example, a polysilicon film 24 formed on the gate insulation layer 22, and a metal silicide film 26 formed on the polysilicon film 24. The polysilicon film 24 may be doped with impurities such as, for example, boron, BF₂, a combination thereof, or any other suitable impurity or impurities. The metal silicide film 26 may include, for example, tungsten silicide, tantalum silicide, titanium silicide, or any other suitable metal silicide. For example, the polysilicon is deposited on the gate insulation layer 22 by an LPCVD process, and impurities such as boron or BF₂ may be implanted into the deposited polysilicon, which may form the polysilicon film 24 on the gate insulation layer 22. Metal silicide such as, for example, tungsten silicide may be deposited on the polysilicon film 24, which may form the metal silicide film 26.

A mask layer 30 may be formed on the gate conductive layer 28. The mask layer 30 may be formed using, for example, a nitride such as silicon nitride or any other suitable nitride.

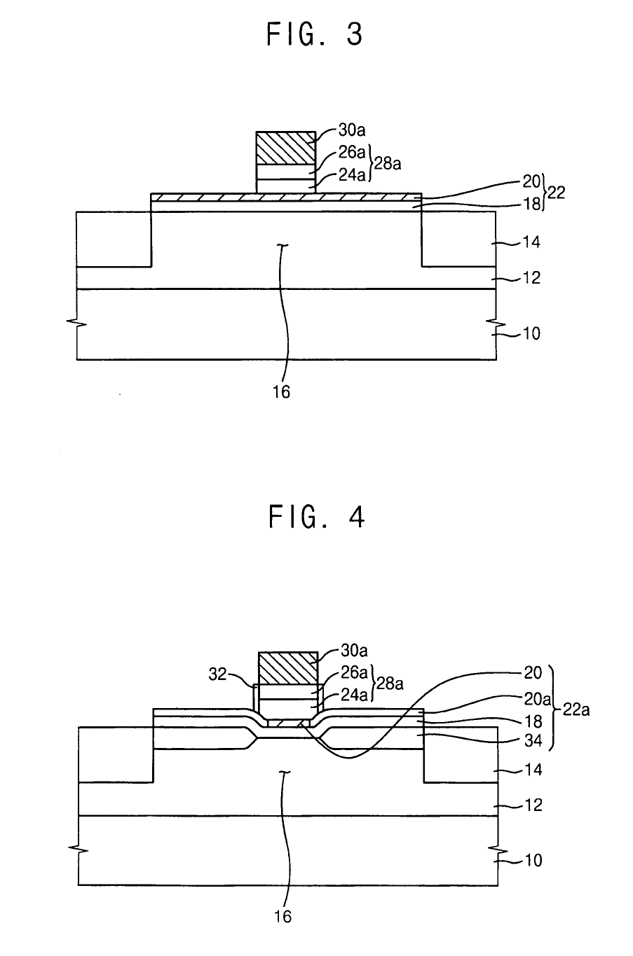

Referring to FIG. 3, a photoresist film may be coated on the mask layer 30, and the photoresist film may be exposed and developed, which may form a photoresist pattern (not shown) on the mask layer 30.

Using the photoresist pattern as an etching mask, the mask layer 30 and the gate conductive layer 28 may be etched (e.g., partially etched) to form a mask pattern 30a and a gate electrode 28a. The mask pattern 30a and the gate electrode 28a may be formed on the gate insulation layer 22 using, for example, a dry etching process or any other suitable etching process. The gate electrode 28a may include a polysilicon film pattern 24a and a metal silicide film pattern 26a formed (e.g., sequentially formed) on the gate insulation layer 22. The mask pattern 30a may be positioned on the gate electrode 28a.

In the etching process for forming the gate electrode 28a, the gate insulation layer 22 and/or the semiconductor substrate 10 exposed by the gate electrode 28a may be damaged. The damage to the gate insulation layer 22 and/or the substrate 10 may deteriorate a quality of the gate insulation layer 22 and/or cause a leakage current through the gate insulation layer 22, which may deteriorate refresh characteristics of a semiconductor device including the damaged gate insulation layer 22.

Referring to FIG. 4, the substrate 10 and the gate insulation layer 22 may be oxidized using, for example, oxygen radicals (O*), or any other suitable free radical, which may be referred to as a gate polysilicon re-oxidation process.

The re-oxidation process may be carried out with respect to the gate insulation layer 22 and the substrate 10 including the gate electrode 28a, for example, using oxygen radicals. The oxygen radicals may be dissociated from a source gas including, for example, H₂, O₂, a combination thereof, or any other suitable gas, at a temperature of, for example, above about 800° C. and/or under a pressure of below about 1 Torr. When the re-oxidation process is performed, a sidewall of the gate electrode 28a may be oxidized (e.g., partially oxidized) to form a second oxide film 32 on the sidewall of the gate electrode 28a. The second oxide film 32 may include, for example, silicon oxide or any other suitable oxide material. The bonds of Si—N in the nitride film 20 exposed by the gate electrode 28a may be transformed into bonds of Si—O, which may form a third oxide film 20a and may cure the damage to the nitride film 20 and/or the damage to the first oxide film 18. At least a portion of the nitride film 20 may be changed into the third oxide film 20a, while another portion of the nitride film 20 positioned beneath the gate electrode 28a may not. A fourth oxide layer 34 may be formed between the substrate 10 and the gate insulation layer 22 due to the oxygen radicals in re-oxidation process and may cure the damage to the substrate 10.

In an example embodiment of the present invention, as the bonds of Si—N in the nitride layer 20 may convert into the bonds of Si—O, the damage to the substrate 10 and/or the gate insulation layer 22 (exposed by the gate electrode 28a) containing the bonds of Si—N may be cured, and a gate insulation structure 22a of a higher quality and/or improved refresh characteristics of the semiconductor device may be obtained. The gate insulation structure 22a may include, for example, the fourth oxide film 34, the first oxide film 18, the third oxide film 20a, and the nitride film 20, although other suitable combinations may be used.

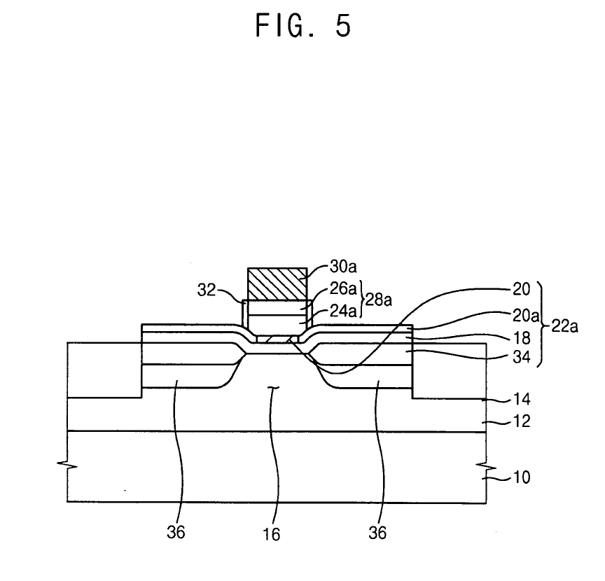

As shown in FIG. 5, an ion implantation process may be performed with a higher energy, for example, using the mask pattern 30a as an implantation mask, which may form source/drain regions 36 having higher concentrations of P+ impurities. As a result, a PMOS transistor may be formed on the substrate 10.

As the bonds of Si—N in the nitride layer 20 convert into bonds of Si—O, the damage to the substrate 10 and/or the gate insulation layer 22 exposed by the gate electrode 28a may be cured, and the gate insulation structure 22a that may have a higher grade and/or improved refresh characteristics of the semiconductor device including the gate insulation structure 22a may be obtained.

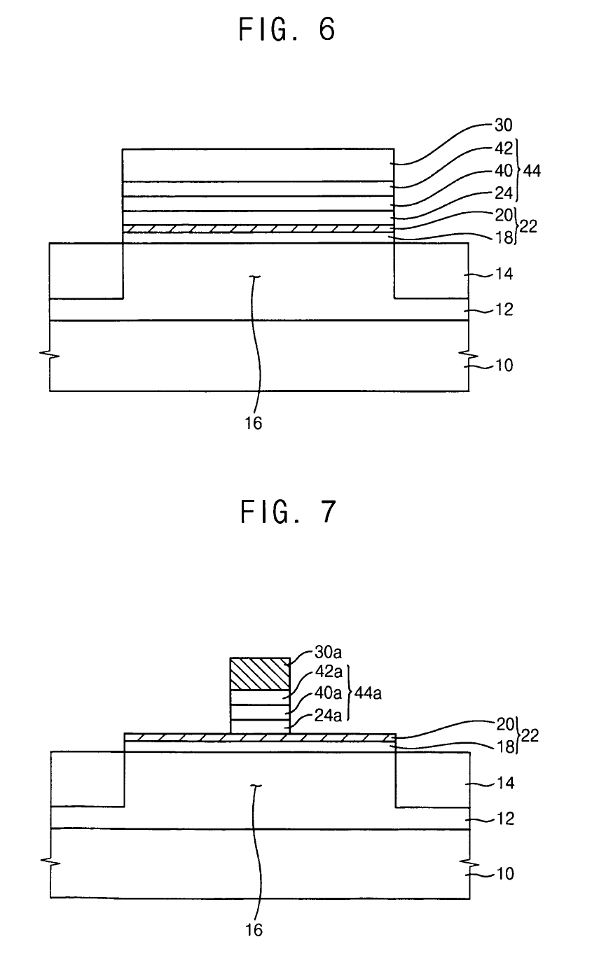

FIGS. 6 to 10 are cross-sectional views illustrating a method of manufacturing a PMOS transistor, according to an example embodiment of the present invention.

In order to reduce a resistance of a gate electrode, the gate electrode may include a polysilicon film pattern doped with impurities, a barrier film pattern and a metal film pattern. In a re-oxidation process, since the metal film pattern may be over-oxidized, a spacer may be formed on a sidewall of the gate electrode before the re-oxidation process.

Referring to FIG. 6, an N-type well 12 doped with N-type impurities may be formed on a semiconductor substrate 10 doped with P-type impurities. An isolation layer 14, for example, a field oxide layer, or any other suitable oxide layer, for defining an active region 16, may be formed on the semiconductor substrate 10.

A gate insulation layer 22 containing bonds of, for example, Si—N, or any other suitable chemical bond, may be formed on the active region 16 of the semiconductor substrate 10. The gate insulation layer 22 including the bonds of Si—N may include, for example, a first oxide film 18 and a first nitride film 20, which may be formed (e.g., sequentially formed) on the active region 16. The first oxide film 18 and the first nitride film 20 may include, for example, silicon oxide, or any other suitable oxide material, and, for example, silicon nitride, or any other suitable nitride material, respectively.

A gate conductive layer 44 and a mask layer 30 may be formed (e.g., sequentially formed) on the gate insulation layer 22. The gate conductive layer 44 may include a P+ type polysilicon film 24 doped with impurities such as, for example, boron, or any other suitable impurity, a barrier film 40 and a metal film 42. The barrier film 40 may include a metal nitride such as, for example, a tungsten nitride or any other suitable metal nitride material, and the metal film 42 may include tungsten or any other suitable metal. The mask layer 30 may be formed on the gate conductive layer 44 using, for example, a nitride such as, for example, silicon nitride, or any other suitable nitride.

Referring to FIG. 7, a photoresist film may be coated on the mask layer 30, and the photoresist film may be exposed and developed to form a photoresist pattern (not shown) on the mask layer 30.

Using the photoresist pattern as an etching mask, the mask layer 30 and the gate conductive layer 44 may be etched (e.g., partially etched) to form a mask pattern 30a and the gate electrode 44a. The mask layer 30 and the gate conductive layer 44 may be etched (e.g., partially etched) using, for example, a dry etching process or any other suitable etching process. The gate electrode 44a may include a polysilicon film pattern 24a, a barrier film pattern 40a and a metal film pattern 42a formed (e.g., successively formed) on the gate insulation layer 22.

For example, in the etching process for forming the gate electrode 44a, the gate insulation layer 22 exposed by the gate electrode 44a and the substrate 10 may be damaged. The damage to the gate insulation layer 22 and/or the substrate 10 may lower a quality of the gate insulation layer 22, and/or cause a leakage current through the gate insulation layer 22, which may deteriorate refresh characteristics of a semiconductor device including the damaged gate insulation layer 22.

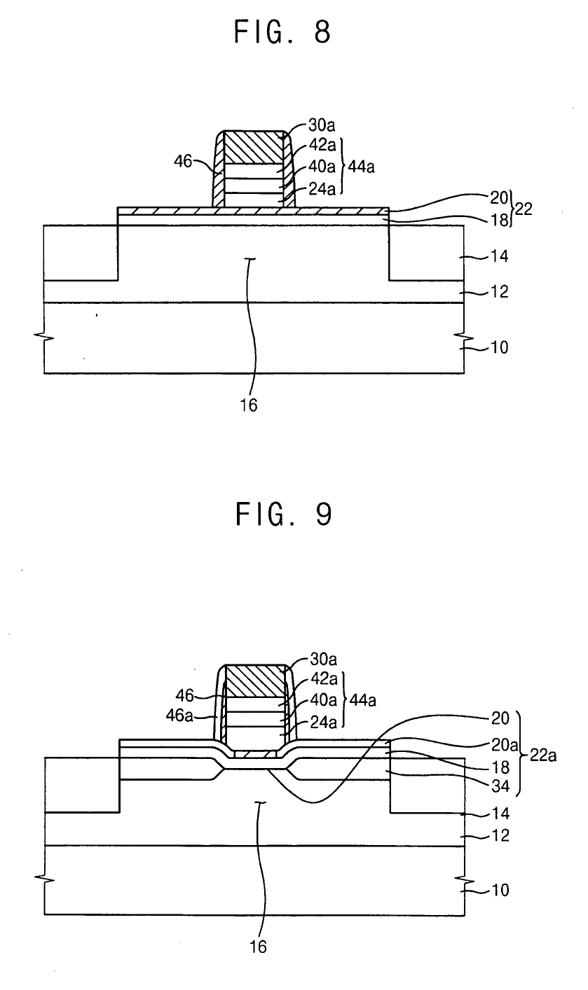

As illustrated in FIG. 8, a second nitride film may be formed on the first nitride film 20 and may cover the gate electrode 44a and the mask pattern 30a. The second nitride film may be formed using, for example, silicon nitride or any other suitable nitride material.

An anisotropic etching process, or any other suitable etching process, may be performed on the second nitride film to form a spacer 46 on sidewalls of the gate electrode 44a and the mask pattern 30a.

When the spacer 46 is formed on the sidewalls the gate electrode 44a and the mask pattern 30a, the gate insulation layer 22 and/or the substrate 10 may be damaged. A thickness of the spacer 46 may be adjusted to suppress an oxidation of the metal film pattern 42a in a re-oxidation process using oxygen radicals, which may cure the damage to the gate insulation layer 22 and/or the substrate 10.

Referring to FIG. 9, the re-oxidation process may be performed on the substrate 10 and the gate insulation layer 22 using, for example, oxygen radicals or any other suitable free radical. In the re-oxidation process, the oxygen radicals may be dissociated from a gas mixture of, for example, H₂ and O₂, or any other suitable gas mixture, at a temperature of above about 800° C. under a pressure of below about 1 Torr. The bonds of Si—N in the spacer 46 formed in the sidewall of the gate electrode 44a may be converted (e.g., partially converted) into, for example, bonds of Si—O to form a second oxide film 46a, and the bonds of Si—N in the first nitride layer 20 exposed by the gate electrode 44a may be changed into bonds of, for example, Si—O to form a third oxide film 20a, and the damage to the first nitride film 20, the spacer 46, and/or the first oxide film 18 may be cured. While curing the damage to the semiconductor substrate 10, a fourth oxide film 34 may be formed between the substrate 10 and the gate insulation layer 22 and a gate insulation structure 22a may be formed between the substrate 10 and the gate electrode 44a. The gate insulation structure 22a may include, for example, the fourth oxide film 34, the first oxide film 18, the first nitride film 20 and the third oxide film 20a, although other combinations may be used.

In example embodiments of the present invention, as the bonds of Si—N in the first nitride film 20 transform into the bonds of Si—O, damage to the gate insulation layer 22 containing the bonds of Si—N and/or the substrate 10 (which are exposed by the gate electrode 44a and the insulation layer spacer 46) may be cured, such that a gate insulation structure 22a of a higher quality may be obtained and/or the refresh characteristics of the semiconductor device may be improved.

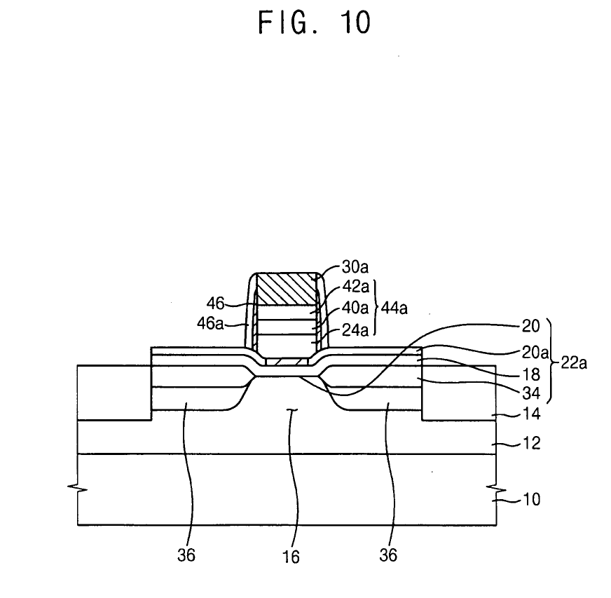

Referring to FIG. 10, an ion implantation process may be performed with a higher energy using, for example, the mask pattern 30a as an ion implantation mask to form source/drain regions 36 with higher concentrations of P+ type impurities at portion of the substrate 10 adjacent to the gate electrode 44a. Thus, a PMOS transistor may be formed on the substrate 10.

As the bonds of Si—N in the first nitride film 20 are converted into the bonds of Si—O, the damage to the semiconductor substrate 10 and/or the gate insulation layer 22 exposed by the gate electrode 44a may be cured, which may obtain the gate insulation structure 22a with improved quality and/or improved refresh characteristics of the semiconductor device

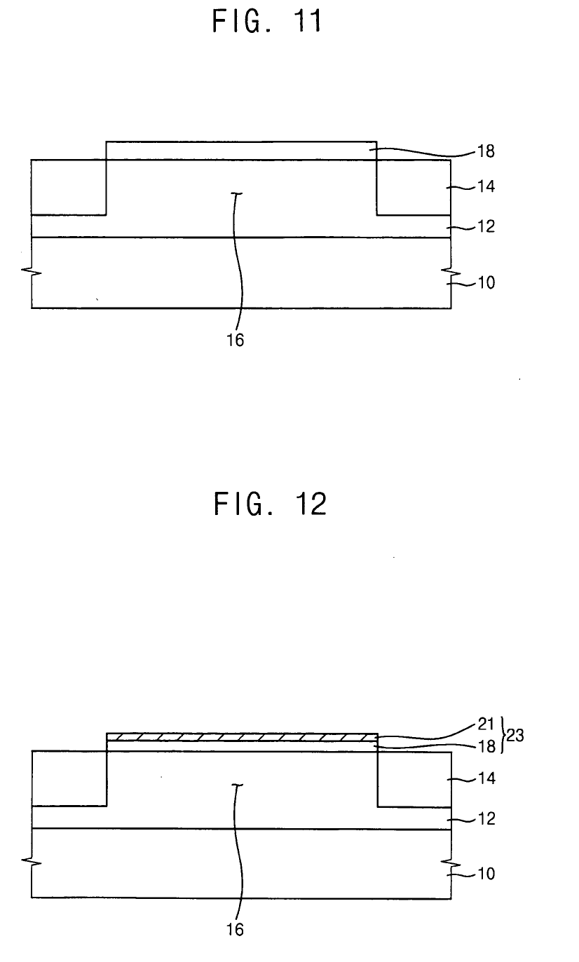

FIGS. 11 and 12 are cross-sectional views illustrating a method of manufacturing a PMOS transistor, according to an example embodiment of the present invention.

With regard to FIGS. 11 and 12, an oxide film may be formed on a semiconductor substrate, and the oxide film may be nitrified (e.g., partially nitrified) in a nitrogen atmosphere to form, for example, an oxynitride film on the substrate.

Referring to FIG. 11, an N-type well 12 doped with N-type impurities may be formed on a semiconductor substrate 10 doped with P-type impurities.

An isolation layer 14 may be formed on the semiconductor substrate 10 to define an active region 16 on the substrate 10.

A first oxide film 18 may be formed on the active region 16 of the semiconductor substrate 10. The first oxide film 18 may be formed using, for example, silicon oxide or any other suitable oxide material.

Referring to FIG. 12, an upper portion of the first oxide film 18 may be nitrified in a nitrogen atmosphere to form, for example, an oxynitride film 21 on the first oxide film 18, and a gate insulation layer 23 containing bonds of Si—N may be formed on the active region 16 of the semiconductor substrate 10. The gate insulation layer 23 may include the first oxide film 18 and the oxynitride film 21 formed (e.g., sequentially formed) on the substrate 10.

The oxynitride film 21 may be formed by treating the first oxide film 18 using, for example, a plasma nitrification process, an annealing process, or any other suitable process. When the oxynitride film 21 is formed by the plasma nitrification process, the first oxide film 18 may be nitrified using a nitrogen (N₂) gas, an ammonia (NH₃) gas, a the mixture thereof, or any other suitable gas or combination of gases, in, for example, a decoupled plasma mode as a plasma generating source or any other suitable generating source. When the oxynitride film 21 is formed by the annealing process, the first oxide film 18 may be nitrified using nitrogen dioxide, nitrogen monoxide, or any other suitable gas or combination of gases, in, for example, a furnace.

A PMOS transistor may be formed on the substrate 10 by processes identical, or substantially identical, to those described with reference to FIGS. 2 to 5 or FIGS. 6 to 10.

Example embodiments of the present invention, as discussed herein, relate to methods of manufacturing semiconductor devices such as, for example, PMOS transistors. However, it will be understood that example embodiments of the present invention may be used in manufacturing other semiconductor devices, for example, NMOS transistors, CMOS (complimentary metal oxide semiconductor) devices, etc.

Example embodiments of the present invention have been described with regard to bonds (e.g., Si—N, etc.), materials (e.g., polysilicon, oxynitride, etc.), elements (e.g., boron, BF₂, etc.) and/or specific processes (e.g., ALD, LCVD, etc.). However, it will be understood that any suitable elements, combination of elements, processes, and/or combination of processes in conjunction with example embodiments of the present invention.

Example embodiments of the present invention have been described with regard to, for example, specific temperature, temperature ranges, exposure times, and pressures. However, it will be understood that any suitable temperature, temperature ranges, exposure times, and/or pressures may be used alone or in combination with one another in example embodiments of the present invention.

As the bonds of Si—N are transformed-into the bonds of Si—O, damage to the semiconductor substrate 10 may be cured such that the gate insulation layer 23 of a higher quality may be obtained and refresh characteristics of a semiconductor device including the gate insulation layer 23 may be enhanced.

While example embodiments of the present invention have been described, the description is illustrative of the invention and not to be construed as limiting the invention. Various modifications and variations may occur to those skilled in the art without departing from the scope and spirit of the invention as defined by the appended claims.

1. A method of manufacturing a semiconductor device, the method comprising:
forming an insulation layer containing bonds of Si—N on a substrate;
forming an electrode on the insulation layer; and
treating the substrate and the insulation layer exposed by the electrode with oxygen radicals such that an insulation capacity of the insulation layer is improved and a surface of the substrate is at least partially oxidized.

2. The method of claim 1, wherein the bonds of Si—N in the insulation layer are at least partially transformed into bonds of Si—O by the oxygen radicals.

3. The method of claim 1, wherein the oxygen radicals are obtained using a gas mixture including at least one of H₂ and O₂.

4. The method of claim 3, wherein the oxygen radicals are formed at at least one of a temperature of above about 800° C. and a pressure of below about 1 Torr.

5. The method of claim 1, wherein forming the insulation layer includes,
forming an oxide film on the substrate, and
forming a nitride film on the oxide film.

6. The method of claim 5, wherein the oxide film includes silicon oxide, and the nitride film includes silicon nitride.

7. The method of claim 1, wherein forming the insulation layer includes,
forming an oxide film on the substrate, and
nitrifying an upper portion of the oxide film in a nitrogen atmosphere to form an oxynitride layer.

8. The method of claim 7, wherein the oxide film includes silicon oxide, and the oxynitride film includes silicon oxynitride.

9. The method of claim 1, wherein forming the electrode includes,
forming a conductive layer on the insulation layer,
forming a mask layer on the conductive layer, and
forming a mask pattern and the electrode by patterning the mask layer and the conductive layer.

10. The method of claim 9, wherein forming the conductive layer includes,
forming a polysilicon film doped with impurities on the insulation layer, and
forming a metal silicide film on the polysilicon film.

11. The method of claim 10, wherein the impurities include at least one of boron and BF₂.

12. The method of claim 1, further including,
forming a spacer on a sidewall of the electrode; and wherein
the treating of the substrate further includes treating the spacer with free radicals.

13. The method of claim 12, wherein forming the insulation layer includes,
forming an oxide film on the substrate, and
forming a nitride film on the oxide film.

14. The method of claim 13, wherein the oxide film comprises silicon oxide, and the nitride film includes silicon nitride.

15. The method of claim 12, wherein forming the insulation layer includes,
forming an oxide film on the substrate, and
nitrifying an upper portion of the oxide film in a nitrogen atmosphere to form an oxynitride film.

16. The method of claim 15, wherein the oxide film includes silicon oxide, and the oxynitride film includes silicon oxynitride.

17. The method of claim 12, wherein forming the electrode includes,
forming a conductive layer on the insulation layer,
forming a mask layer on the conductive layer, and
forming a mask pattern and the electrode by patterning the mask layer and the conductive layer.

18. The method of claim 17, wherein forming the conductive layer includes,
forming a polysilicon film doped with impurities on the insulation layer,
forming a barrier film on the polysilicon film, and
forming a metal film on the barrier film.

19. The method of claim 18, wherein the impurities include at least one of boron and BF₂.

20. The method of claim 18, wherein the barrier film includes tungsten nitride, and the metal film includes tungsten.

21. A method of manufacturing a semiconductor device, the method comprising:
forming an insulation layer on a substrate;
forming an electrode on the insulation layer; and
treating the substrate and the insulation layer exposed by the electrode with free radicals such that an insulation capacity of the insulation layer is improved and a surface of the substrate is at least partially oxidized.

22. The method of claim 21, further including,
forming a spacer on a sidewall of the electrode; and wherein
the treating of the substrate further includes treating the spacer with free radicals.
